(19) United States
(12) Patent Application Publication
(10) Pub. No.: US 2013/0312804 A1
(43) Pub. Date: Nov. 28, 2013

(54) TOUCH PANEL

(71) Applicant: FUJITSU COMPONENT LIMITED, Tokyo (JP)

(72) Inventors: Shinichiro Akieda, Tokyo (JP); Mitsuhiro Sekizawa, Tokyo (JP)

(73) Assignee: FUJITSU COMPONENT LIMITED, Tokyo (JP)

(21) Appl. No.: 13/890,703

(22) Filed: May 9, 2013

(30) Foreign Application Priority Data
May 23, 2012 (JP) 2012-117583

(51) Int. Cl. H01L 31/058

(52) U.S. Cl. CPC H01L 31/0583
USPC 136/205

(57) ABSTRACT

A touch panel includes: an illuminant that emits light from an opening provided on a non-operation area of a film; and at least one of a photoelectric converter that generates an electric power based on the light emitted from the illuminant and a thermoelectric converter that generates an electric power based on a temperature difference between a temperature of an operation surface of the touch panel and a temperature inside the touch panel; wherein the illuminant and the at least one of the photoelectric converter and the thermoelectric converter are arranged between an upper substrate and a lower substrate of the touch panel, and arranged below the non-operation area of the film.

### CROSS-REFERENCE TO RELATED APPLICATION

This application is based upon and claims the benefit of priority of the prior Japanese Patent Application No. 2012-117583 filed on May 23, 2012, the entire contents of which are incorporated herein by reference.

### FIELD

A certain aspect of the embodiments is related to a touch panel.

### BACKGROUND

Conventionally, there have been known a mobile terminal and a display device that have a photoelectric converter or a solar battery (e.g. see Japanese Laid-open Patent Publication No. 2003-84281, Japanese Laid-open Patent Publication No. 2004-102677, and Japanese Laid-open Patent Publication No. 2000-19983). In addition, there has been conventionally known a display device that has a thermoelectric converter (e.g. see Japanese Laid-open Patent Publication No. 2006-293062).

### SUMMARY

According to an aspect of the present invention, there is provided a touch panel including: an illuminant that emits light from an opening provided on a non-operation area of a film; and at least one of a photoelectric converter that generates an electric power based on the light emitted from the illuminant and a thermoelectric converter that generates an electric power based on a temperature difference between a temperature of an operation surface of the touch panel and a temperature inside the touch panel; wherein the illuminant and the at least one of the photoelectric converter and the thermoelectric converter are arranged between an upper substrate and a lower substrate of the touch panel, and arranged below the non-operation area of the film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded diagram of a touch panel according to the present embodiment;

FIG. 2 is a diagram of transparent configuration of the touch panel, as viewed from above;

FIG. 3 is an exploded diagram of a variation of the touch panel according to the present embodiment;

FIG. 4 is a diagram of transparent configuration of the touch panel in FIG. 3, as viewed from above;

FIG. 5 is a block diagram of an information processing apparatus equipped with the touch panel;

FIG. 6A is a diagram illustrating schematic configuration of a photoelectric converter;

FIG. 6B is a diagram illustrating schematic configuration of a thermoelectric converter;

FIG. 7A is a cross-section diagram illustrating schematic configuration of the touch panel in FIG. 1;

FIG. 7B is a cross-section diagram illustrating schematic configuration of the touch panel in FIG. 3;

FIG. 8A is a cross-section diagram illustrating schematic configuration of a first variation of the touch panel in FIG. 7A;

FIG. 8B is a cross-section diagram illustrating schematic configuration of a first variation of the touch panel in FIG. 7B;

FIG. 9A is a cross-section diagram illustrating schematic configuration of a second variation of the touch panel in FIG. 7A;

FIG. 9B is a cross-section diagram illustrating schematic configuration of a second variation of the touch panel in FIG. 7B;

FIG. 10A is a cross-section diagram illustrating schematic configuration of a third variation of the touch panel in FIG. 7A;

FIG. 10B is a cross-section diagram illustrating schematic configuration of a third variation of the touch panel in FIG. 7B;

FIG. 11A is a cross-section diagram illustrating schematic configuration of a fourth variation of the touch panel in FIG. 7A;

FIG. 11B is a cross-section diagram illustrating schematic configuration of a fourth variation of the touch panel in FIG. 7B;

FIG. 12A is a cross-section diagram illustrating schematic configuration of a fifth variation of the touch panel in FIG. 7A; and

FIG. 12B is a cross-section diagram illustrating schematic configuration of a fifth variation of the touch panel in FIG. 7B.

### DESCRIPTION OF EMBODIMENTS

Hereinafter, a description will be given of embodiments of the present invention with reference to the drawings.

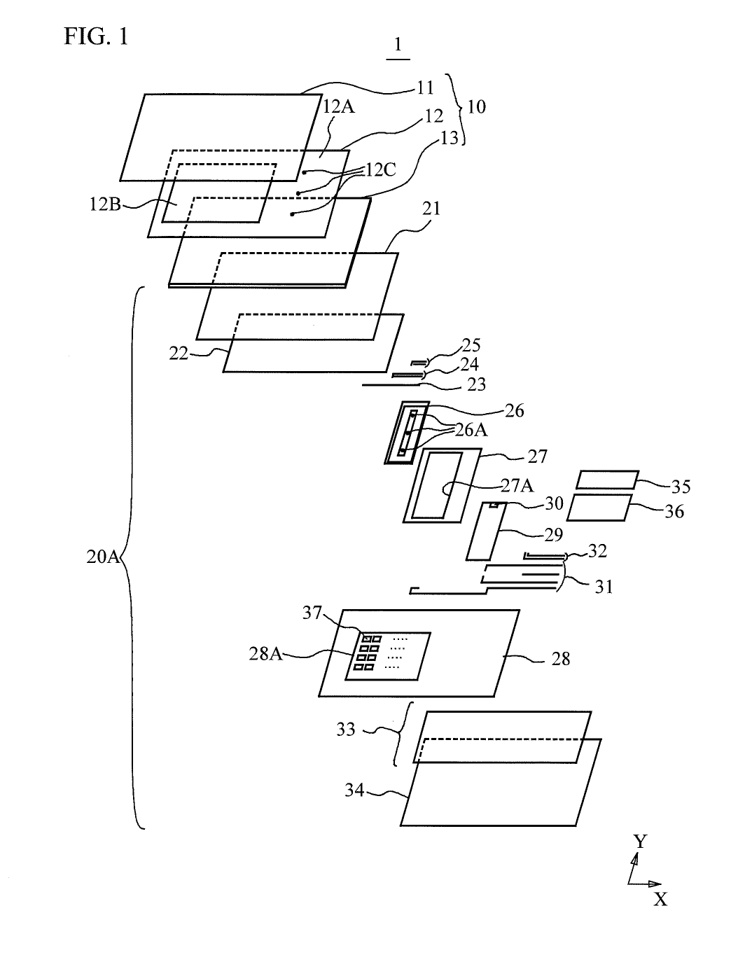

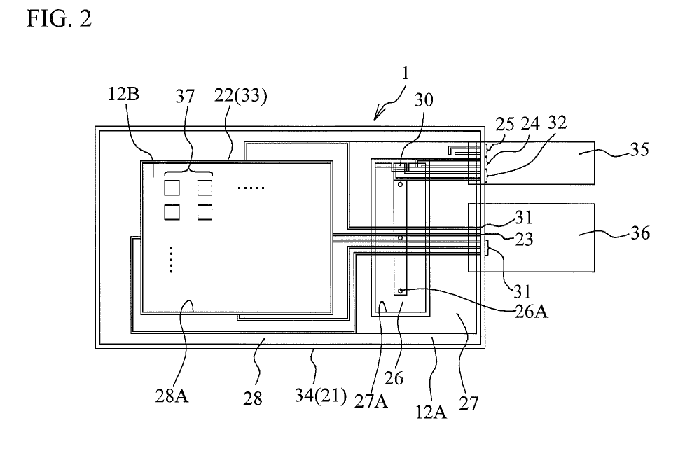

FIG. 1 is an exploded diagram of a touch panel according to the present embodiment. FIG. 2 is a diagram of transparent configuration of the touch panel, as viewed from above. In FIGS. 1 and 2, a touch panel 1 is a resistive membrane touch panel. The touch panel 1 includes a cover film 10 and a main body 20A.

The cover film 10 includes: a cover 11 that protects an operation surface of the touch panel 1; a print layer 12 that prints a logo 12C including a character or a figure; and an adhesive 13. The cover is made of hard coat PET (Polyethylene terephthalate), polycarbonate, or glass. Decoration print of the print layer 12 is performed with an ink on a lower surface of the cover 11. The print layer 12 includes: a decoration area 12A for appearance design (i.e., a non-operation area where a user does not input an operation instruction); an operation area 12B where the user inputs the operation instruction. The logo 12C is formed on the decoration area 12A as an opening which penetrates the light from the inside of the touch panel 1 to the operation surface (namely, the outside of the touch panel 1). As for the logo 12C, the outline of the character or the figure is drawn like an outline character.

The adhesive 13 is an OCA (optical clear adhesive) or a double-sided tape for pasting up the cover film 10 on the main body 20A.

The main body 20A includes an upper substrate 21, an upper transparent electrode 22, a wiring 23 for the upper transparent electrode, wirings 24 for a photoelectric converter, wirings 25 for a thermoelectric converter, a photoelectric converter 26, a thermoelectric converter 27, an adhesive 28, a light-guiding plate 29, and an illuminant 30. Moreover, the main body 20A includes wirings 31 for a lower transparent electrode, wirings 32 for the illuminant, a lower transparent electrode 33, a lower substrate 34, a first FPC (Flexible printed circuit) 35, a second FPC 36, and spacers 37. The wiring 23 and the wirings 31 are made of silver paste, for example, and are printed on the upper substrate 21 and the lower substrate 34, respectively. The wirings 24, the wirings 25, and the wirings 32 are also made of silver paste, for example, and are printed on the upper substrate 21 and/or the lower substrate 34.

Each of the upper substrate 21 and the lower substrate 34 is made of PET (Polyethylene terephthalate), polycarbonate, or glass. The upper transparent electrode 22 is connected to the wiring 23, and detects a voltage of a position where the touch panel 1 is depressed (specifically, respective voltages in an X-direction and a Y-direction). The upper transparent electrode 22 and the lower transparent electrode 33 are made of an ITO (Indium Tin Oxide) film, silver nanowire (AgNW), or OCP (Organic Conductive Polymer).

The illuminant 30 is made of a LED (Light Emitting Diode), an organic EL (Organic Electro-Luminescence), or a liquid crystal panel, and emits light by an electric power supplied from the wirings 32. The light-guiding plate 29 diffuses the light emitted from the illuminant 30.

The photoelectric converter 26 is made of a dye-sensitized solar cell, for example. The photoelectric converter 26 receives the light from the illuminant 30 directly or via the light-guiding plate 29, generates an electric power from the received light, and accumulates the generated electric power into an accumulator described later, via the wirings 24. Penetration holes 26A which penetrate a part of the light emitted from the illuminant 30 to the logo 12c are formed on the photoelectric converter 26.

In an example of FIG. 1, the photoelectric converter 26 is opposed to the light-guiding plate 29 and the illuminant 30 which have the substantially same area as the area of the photoelectric converter 26 in planar view. In addition, the photoelectric converter 26 is arranged so that the penetration holes 26A are opposed to the logo 12C. In the example of FIG. 1, a part of the light emitted from the illuminant 30 proceeds to the operation surface of the touch panel 1 via the penetration holes 26A and the logo 12C, and remaining light is used for the electric power generation of the photoelectric converter 26. Therefore, the light emitted from the illuminant 30 can be efficiently used for the lighting of the logo 12C and the electric power generation of the photoelectric converter 26. That is, light (i.e., leakage light) which is not used for the lighting of the logo 12C and the electric power generation of the photoelectric converter 26 can be reduced.

The thermoelectric converter 27 generates an electric power from a temperature difference between a temperature of the surface of the cover 11 (i.e., the cover film 10) and a temperature inside the touch panel 1, and accumulates the generated electric power into the accumulator described later, via the wirings 25. A through-hole 27A for arranging at least one of the photoelectric converter 26 and the illuminant 30 is formed on the thermoelectric converter 27. In the example of FIG. 1, the photoelectric converter 26, the light-guiding plate 29 and the illuminant 30 are arranged in the through-hole 27A. Thereby, since at least one of the photoelectric converter 26 and the illuminant 30 is arranged in the through-hole 27A as a heat source, it is easy for the thermoelectric converter 27 to measure the temperature from the heat source. The shape of the thermoelectric converter 27 is not limited to a shape as illustrated in FIG. 1. For example, the thermoelectric converter 27 may be a rectangle without the through-hole 27A. In this case, the photoelectric converter 26, the light-guiding plate 29 and the illuminant 30 are arranged away from the thermoelectric converter 27.

The adhesive 28 is an OCA (optical clear adhesive) or a double-sided tape, and bonds elements in the main body 20A, at predetermined positions, which are other than the upper substrate 21 and the lower substrate 34 and are arranged between the upper substrate 21 and the lower substrate 34. Here, the adhesive 28 is not arranged on the an area 28A that overlaps the operation area 12B.

Voltages (specifically, respective voltages in an X-direction and a Y-direction) supplied from the wirings 31 are applied to the lower transparent electrode 33. The upper transparent electrode 22 contacts the lower transparent electrode 33, and hence voltages of a contact position are sent to a detection circuit, not shown, via the wiring 23. Thereby, the depression position of the touch panel 1 is detected.

The first FPC 35 is connected to the wirings 24, the wirings 25, and the wirings 32, and has a function that draws out these wirings to the outside of the touch panel 1. The second FPC 36 is connected to the wiring 23 and the wirings 31, and has a function that draws out these wirings to the outside of the touch panel 1. The spacers 37 are provided in order to prevent short-circuit of the upper transparent electrode 22 and the lower transparent electrode 33 at the time of no input.

The spacers 37 and parts of the upper transparent electrode 22 and the lower transparent electrode 33 are arranged below the operation area 12B. On the other hand, elements other than these (e.g. the photoelectric converter 26, the thermoelectric converter 27, the light-guiding plate 29, the illuminant 30, and so on) are arranged below the decoration area 12A. This is because, if the photoelectric converter 26, the thermoelectric converter 27 and so on are arranged below the operation area 12B, they prevent the upper transparent electrode 22 from being in contact with the lower transparent electrode 33, so that the user cannot input the operation instruction.

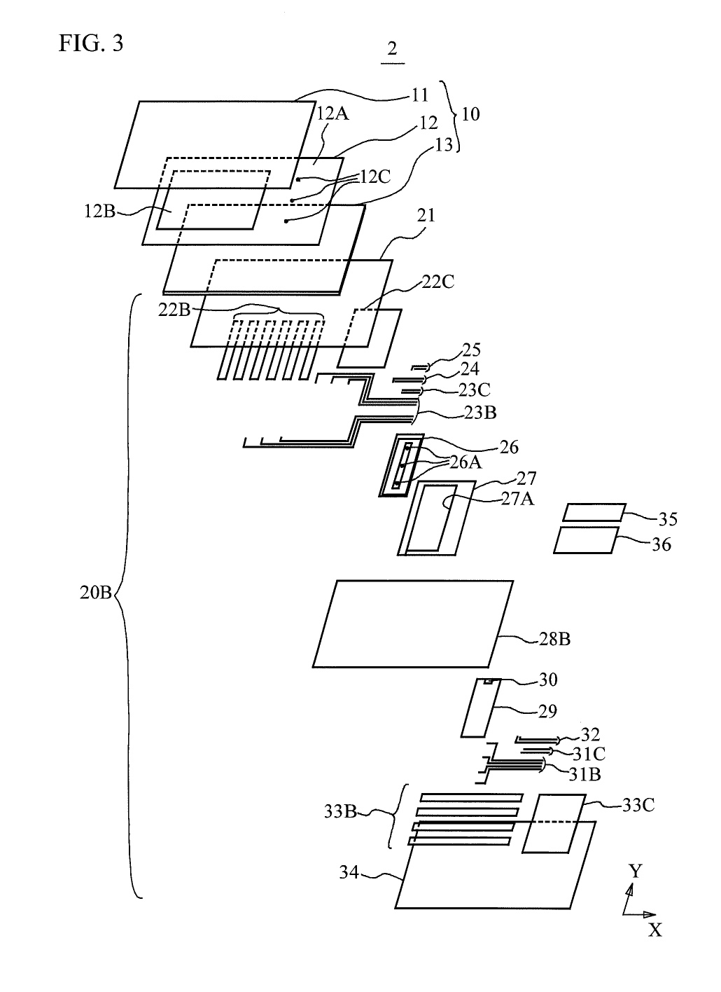

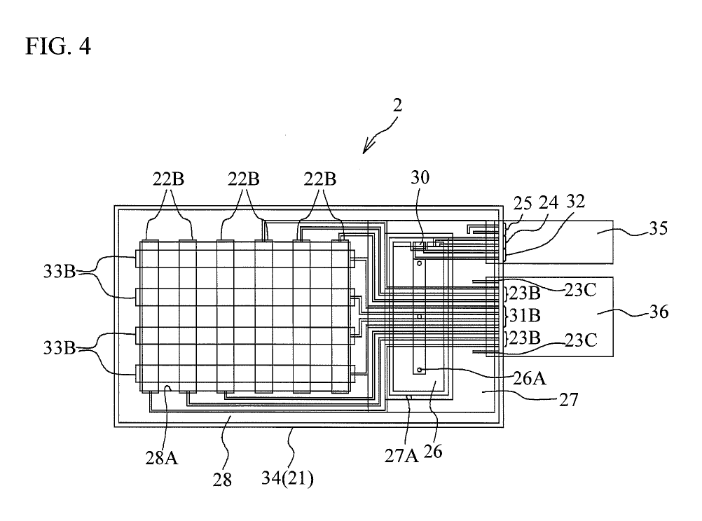

FIG. 3 is an exploded diagram of a variation of the touch panel according to the present embodiment. FIG. 4 is a diagram of transparent configuration of the touch panel in FIG. 3, as viewed from above.

In FIGS. 3 and 4, the touch panel 2 is a projected capacitive touch panel. Elements of the touch panel 2 corresponding to those of the touch panel 1 in FIG. 1 are designated by identical reference numerals, and description thereof is omitted.

The touch panel 2 includes the cover film 10 and a main body 20B, as illustrated in FIG. 3. That is, the touch panel 2 is different from the touch panel 1 in the structure of the main body.

The upper transparent electrode is composed of a plurality of transparent electrodes 22B that extend in a Y-direction and input the operation instruction, and a transparent electrode 22C arranged above the photoelectric converter 26 and the thermoelectric converter 27. Wirings 23B for transparent electrode are connected to the transparent electrodes 22B, respectively. Wirings 23C for transparent electrode are connected to the transparent electrode 22C.

The lower transparent electrode is composed of a plurality of transparent electrodes 33B that extend in an X-direction and input the operation instruction, and a transparent electrode 33C arranged below the photoelectric converter 26 and the thermoelectric converter 27. Wirings 31B for transparent electrode are connected to the transparent electrodes 33B, respectively. Wirings 31C for transparent electrode are connected to the transparent electrode 33C. An adhesive 28B bonds elements in the main body 20B, at predetermined positions, which are other than the upper substrate 21 and the lower substrate 34 and are arranged between the upper substrate 21 and the lower substrate 34.

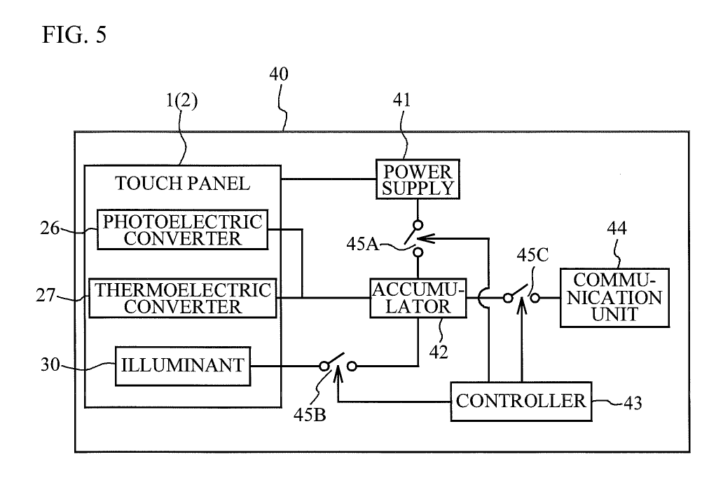

FIG. 5 is a block diagram of an information processing apparatus equipped with the touch panel 1 or 2.

The information processing apparatus 40 is a mobile phone, a computer, or a navigation device, or the like, for example. The information processing apparatus 40 includes the touch panel 1 or 2, a power supply 41, an accumulator 42, a controller 43, a communication unit 44, and switches 45A to 45C. Here, the configuration of the information processing apparatus 40 is not limited to this. For example, the information processing apparatus 40 may have no communication unit 44.

The power supply 41 is an AC-DC power supply or a battery, and supplies an electric power to the touch panel 1 or 2. The accumulator 42 is a rechargeable battery or a capacitor, and accumulates the electric power acquired from the photoelectric converter 26 and the thermoelectric converter 27. The communication unit 44 communicates with an external terminal, not shown. The controller 43 controls the whole information processing apparatus, and controls on/off of the switches 45A to 45C.

When the electric power in the accumulator 42 is supplied to the power supply 41, the controller 43 turns on the switch 45A. In this case, the electric power acquired from the photoelectric converter 26 and the thermoelectric converter 27 is reused for the operation of the touch panel 1 or 2. When the electric power in the accumulator 42 is supplied to the illuminant 30, the controller 43 turns on the switch 45B. In this case, the electric power acquired from the photoelectric converter 26 and the thermoelectric converter 27 is reused for the lighting of the illuminant 30. When the electric power in the accumulator 42 is supplied to the communication unit 44, the controller 43 turns on the switch 45C. In this case, the electric power acquired from the photoelectric converter 26 and the thermoelectric converter 27 is reused for the operation of the communication unit 44. Here, a method of reuse of the electric power acquired from the photoelectric converter 26 and the thermoelectric converter 27 is not limited to these.

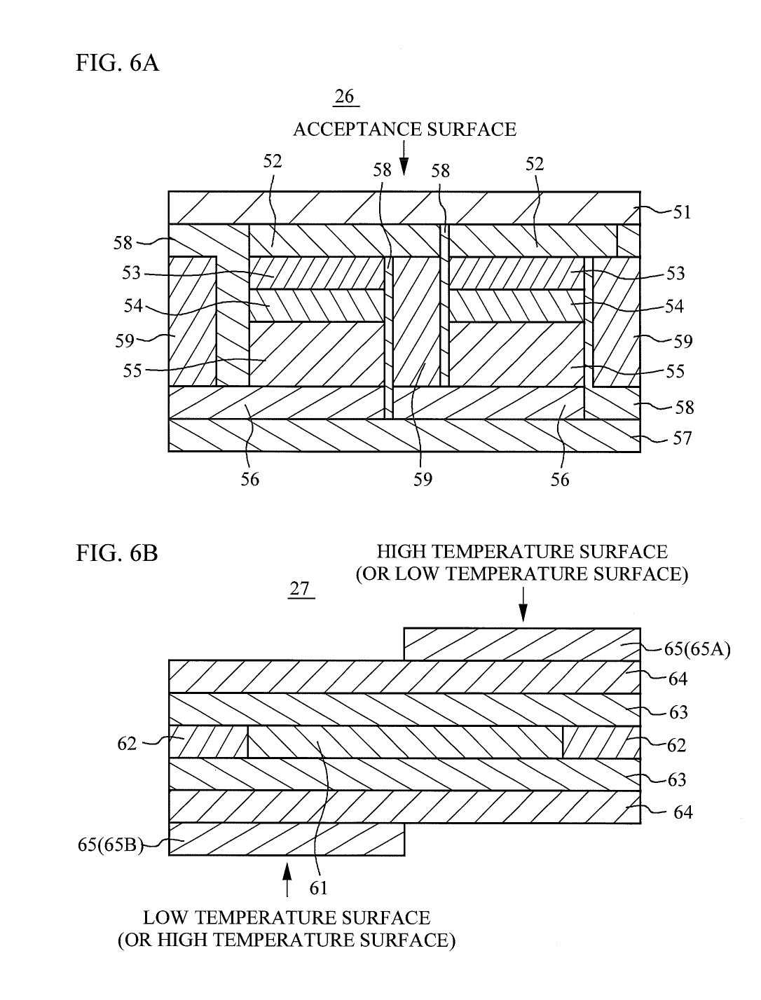

FIG. 6A is a diagram illustrating schematic configuration of the photoelectric converter 26. An acceptance surface of the photoelectric converter 26 is an upper side of FIG. 6A. The photoelectric converter 26 includes a transparent film substrate 51, transparent conducting layers 52, titanium oxides 53, dyes 54, iodine electrolytes 55, platinic antipoles 56, a substrate 57, protective sealing films 58, and connection electrodes 59.

When the light enters into the acceptance surface of the photoelectric converter 26, the dyes 54 become an excitation state and emit electrons. The electrons reach the transparent conducting layers 52 via the titanium oxides (TiO2) 53, and flow to the connection electrodes 59. On the other hand, the dyes 54 that have emitted the electrons and have become positive ions receive the electrons supplied from the platinic antipoles 56 via the iodine electrolytes 55, and hence return to an original state. While the light is entering into the acceptance surface of the photoelectric converter 26, the above-mentioned operation is performed repeatedly and hence the electric power is generated.

FIG. 6B is a diagram illustrating schematic configuration of the thermoelectric converter 27. A thermoelectric conversion material 61 is provided in the center of the thermoelectric converter 27. The thermoelectric conversion material 61 is made of alloys of Bismuth telluride, for example. Electrodes 62 are provided on both ends of thermoelectric conversion material 61. Adhesives 63 are applied to the upper and lower sides of the thermoelectric conversion material 61 and the electrodes 62 so as to sandwich the thermoelectric conversion material 61 and the electrodes 62 from the up-and-down directions thereof. Moreover, insulating polyimide layers 64 are formed so as to sandwich the adhesives 63 from the up-and-down directions thereof. Heat transfer layers 65 are formed so as to sandwich the polyimide layers 64 from the up-and-down directions thereof. The heat transfer layers 65 have an upper heat transfer layer 65A and a lower heat transfer layer 65B, and are made of silver, for example. An upper surface of the upper heat transfer layer 65A and a lower surface of the lower heat transfer layer 65B are reception surfaces of temperature. The upper heat transfer layer 65A receives surface temperature of the cover 11 (i.e., the cover film 10) and the lower heat transfer layer 65B receives temperature inside the touch panel 1 or 2. The thermoelectric conversion material 61 generates an electric power based on a temperature difference between the upper heat transfer layer 65A and the lower heat transfer layer 65B.

The temperature inside the touch panel 1 or 2 is changed according to the usage environment of the touch panel 1 or 2. For example, immediately after startup of the touch panel 1 or 2, the temperature inside the touch panel 1 or 2 may be lower than the surface temperature of the cover 11. When the touch panel 1 or 2 is used for a long time, the temperature inside the touch panel 1 or 2 may be higher than the surface temperature of the cover 11. The temperature inside the touch panel 1 or 2 rises by heat generation of the illuminant 30 or heat generation from each wiring, for example.

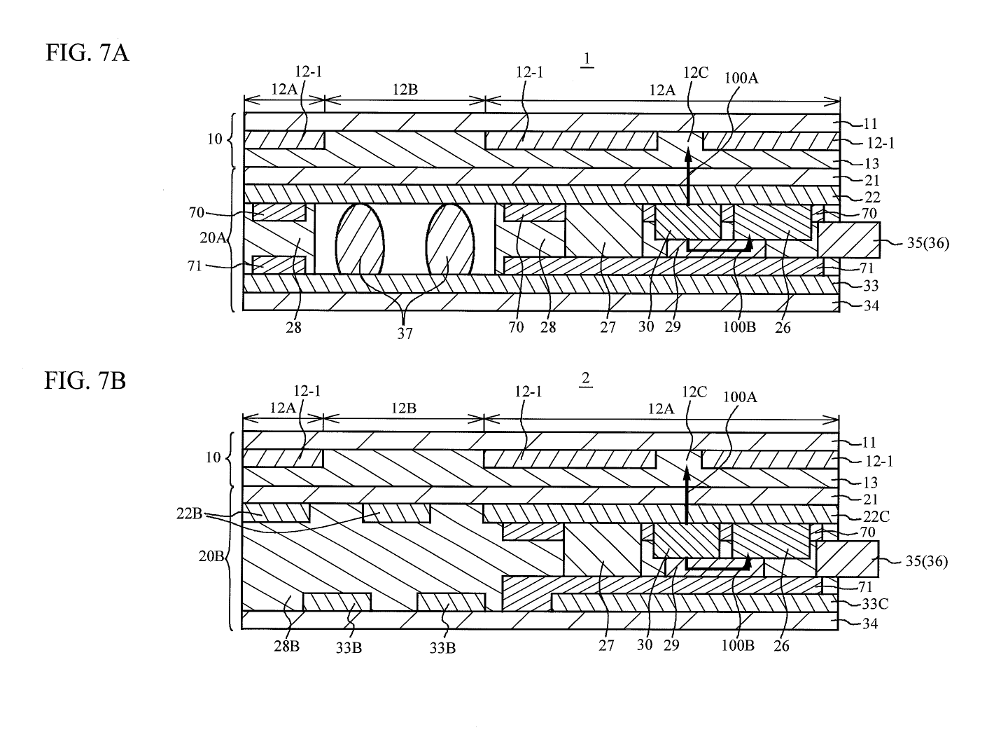

FIG. 7A is a cross-section diagram illustrating schematic configuration of the touch panel 1 in FIG. 1. FIG. 7B is a cross-section diagram illustrating schematic configuration of the touch panel 2 in FIG. 3. In FIGS. 7A to 12B, an upper side of the touch panel 1 or 2 is a side of the operation surface, and a lower side of the touch panel 1 or 2 is a side of a rear surface of the touch panel.

In FIGS. 7A and 7B, ink portions 12-1 of the print layer 12 are printed on a rear surface of the cover 11. The ink portions 12-1 are decoration areas for appearance design and areas which never penetrate the light. Since the ink portions 12-1 are not formed in the operation area 12B where the user inputs the operation instruction, the operation area 12B can penetrate the light. When an illuminant (e.g. an LED), not shown, is arranged below the main body 20B, for example, the light from the illuminant is diffused above the touch panel 1 or 2 (i.e. the side of the operation surface) via the operation area 12B.

In FIG. 7A, the upper transparent electrode 22, the lower transparent electrode 33, upper wirings 70, lower wirings 71, the spacers 37, the photoelectric converter 26, the thermoelectric converter 27, the light-guiding plate 29, the illuminant 30, the first FPC 35 and the second FPC 36 are provided between the upper substrate 21 and the lower substrate 34. The upper wirings 70 include the wiring 23, and the lower wirings 71 include the wirings 31.

In FIG. 7B, the transparent electrodes 22B, 22C, 33B and 33C, the upper wirings 70, the lower wirings 71, the photoelectric converter 26, the thermoelectric converter 27, the light-guiding plate 29, the illuminant 30, the first FPC 35 and the second FPC 36 are provided between the upper substrate 21 and the lower substrate 34. The upper wirings 70 include the wirings 23B and the wirings 23C. The lower wirings 71 include the wirings 31B and the wirings 31C.

In FIGS. 7A and 7B, each of the wirings 24, the wirings 25, and the wirings 32 functions as the upper wirings 70. Each of the wirings 24, the wirings 25, and the wirings 32 may function as the lower wirings 71. Since each of the wirings 24, the wirings 25, and the wirings 32 is a pair of wirings as illustrated in FIG. 1, one of the wirings may function as the upper wirings 70 and another of the wirings may function as the lower wirings 71. The wirings 23B and the wirings 23C function as the upper wirings 70, and the wirings 31B and the wirings 31C function as the lower wirings 71.

In FIGS. 7A and 7B, the illuminant 30 is arranged on the light-guiding plate 29 so as to be opposite to a part of the light-guiding plate 29. Also, the photoelectric converter 26 is arranged on the light-guiding plate 29 so as to be opposite to a part of the light-guiding plate 29. The acceptance surface of the photoelectric converter 26 is looking down, i.e., is in contact with the light-guiding plate 29. Thereby, light 100A emitted from the illuminant 30 proceeds to the logo 12C via the upper transparent electrode 22 or the transparent electrode 22C, the upper substrate 21, and the adhesive 13. Moreover, light 100B emitted from the illuminant 30 proceeds to the photoelectric converter 26 via the light-guiding plate 29. Therefore, the user can confirm light emitting of the logo 12C. Further, the photoelectric converter 26 can generate the electric power by the light 100B emitted from the illuminant 30 (i.e., not external light but light which is entered from below the photoelectric converter 26). In addition, the thermoelectric converter 27 can generate an electric power by the temperature difference between the temperature of the surface of the cover 11 and the temperature inside the touch panel 1 or 2.

According to FIGS. 7A and 7B, the light-guiding plate 29 is adjacent to the illuminant 30 and the acceptance surface of the photoelectric converter 26, so that the size of the illuminant 30 can be reduced. Since the light emitted from the illuminant 30 can be guided to a desired place using the light-guiding plate 29, the flexibility of the arrangement of the illuminant 30 and the photoelectric converter 26 increases.

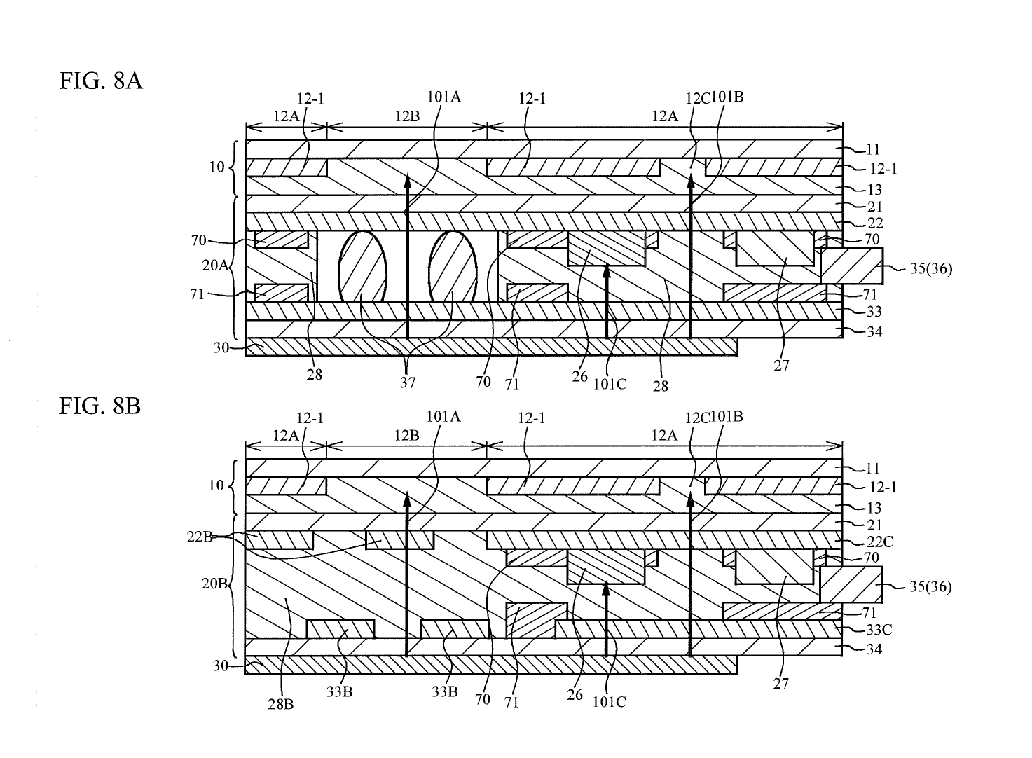

FIG. 8A is a cross-section diagram illustrating schematic configuration of a first variation of the touch panel 1 in FIG. 7A. FIG. 8B is a cross-section diagram illustrating schematic configuration of a first variation of the touch panel 2 in FIG. 7B.

In FIGS. 8A and 8B, the illuminant 30 is arranged below the lower substrate 34 (i.e., on the rear surface of the lower substrate 34). The light-guiding plate 29 is not used. The illuminant 30 is provided at a position opposite to the operation area 12B and the logo 12C. In FIGS. 8A and 8B, the illuminant 30 is made of the simple substance of LED (Light Emitting Diode), organic EL (Organic Electro-Luminescence), or a liquid crystal panel. One illuminant may be provided at a position opposite to the operation area 12B, and another illuminant may be provided at a position opposite to the logo 12C. In case of FIGS. 8A and 8B, the acceptance surface of the photoelectric converter 26 is also looking down.

Light 101A emitted from the illuminant 30 proceeds to the operation area 12B via the lower substrate 34, the lower transparent electrode 33, the upper transparent electrode 22, the upper substrate 21, and the adhesive 13 (see FIG. 8A), or via the lower substrate 34, the adhesive 28B, the transparent electrode 22B, the upper substrate 21 and the adhesive 13 (see FIG. 8B). In this case, the user can confirm light emitting of the operation area 12B. When the operation instruction is input in a dark environment, for example, the light emitting of the operation area 12B is useful.

Light 101B emitted from the illuminant 30 proceeds to the logo 12C via the lower substrate 34, the lower transparent electrode 33, the adhesive 28, the upper transparent electrode 22, the upper substrate 21, and the adhesive 13 (see FIG. 8A), or via the lower substrate 34, the transparent electrode 33C, the adhesive 28B, the transparent electrode 22C, the upper substrate 21 and the adhesive 13 (see FIG. 8B). In this case, the user can confirm light emitting of the logo 12C.

Light 101C emitted from the illuminant 30 proceeds to the photoelectric converter 26 via the lower substrate 34, the lower transparent electrode 33, and the adhesive 28 (see FIG. 8A), or via the lower substrate 34, the transparent electrode 33C, and the adhesive 28B (see FIG. 8B). In this case, the photoelectric converter 26 can generate an electric power by the light 101C emitted from the illuminant 30. The thermoelectric converter 27 can generate an electric power by the temperature difference between the temperature of the surface of the cover 11 and the temperature inside the touch panel 1 or 2.

According to FIGS. 8A and 8B, it is possible to effectively use the light emitted from the illuminant 30 via the logo 12C which is the non-operation area of the cover film 10, or use the heat inside the apparatus (i.e., the heat inside the touch panel 1 or 2). In addition, the illuminant 30 can be provided outside the touch panel 1 or 2. Moreover, the light-guiding plate 29 is not required.

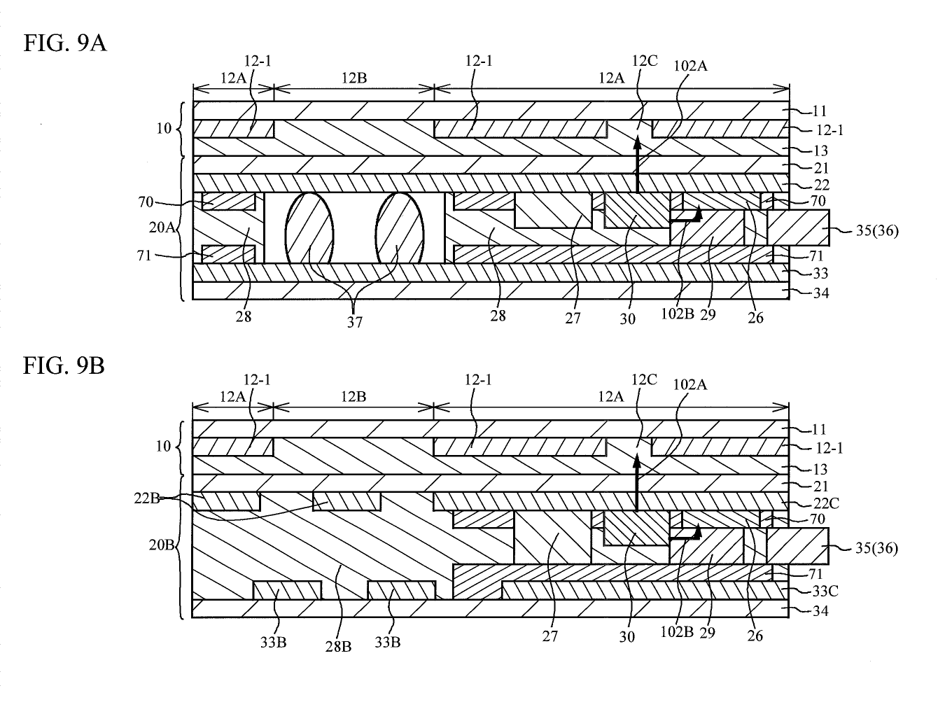

FIG. 9A is a cross-section diagram illustrating schematic configuration of a second variation of the touch panel 1 in FIG. 7A. FIG. 9B is a cross-section diagram illustrating schematic configuration of a second variation of the touch panel 2 in FIG. 7B.

As described above, in FIGS. 7A and 7B, the illuminant 30 is arranged on the light-guiding plate 29 so as to be opposite to a part of the light-guiding plate 29. On the contrary, in FIGS. 9A and 9B, the illuminant 30 is adjacent to a side surface of the light-guiding plate 29 so as to be opposite to a part of the light-guiding plate 29. That is, the illuminant 30 is arranged on an end of the light-guiding plate 29. The photoelectric converter 26 is arranged on the light-guiding plate 29 so as to be opposite to a part of the light-guiding plate 29. In this case, the acceptance surface of the photoelectric converter 26 is also looking down.

Light 102A emitted from the illuminant 30 proceeds to the logo 12C via the upper transparent electrode 22 or the transparent electrode 22C, the upper substrate 21 and the adhesive 13. In addition, light 102B emitted from the illuminant 30 proceeds to the photoelectric converter 26 via the light-guiding plate 29. Therefore, the user can confirm light emitting of the logo 12C. Further, the photoelectric converter 26 can generate an electric power by the light 102B emitted from the illuminant 30. The thermoelectric converter 27 can generate an electric power by the temperature difference between the temperature of the surface of the cover 11 and the temperature inside the touch panel 1 or 2.

According to FIGS. 9A and 9B, the light-guiding plate 29 is adjacent to the illuminant 30 and the acceptance surface of the photoelectric converter 26, so that the size of the illuminant 30 can be reduced. Since the light emitted from the illuminant 30 can be guided to a desired place using the light-guiding plate 29, the flexibility of the arrangement of the illuminant 30 and the photoelectric converter 26 increases.

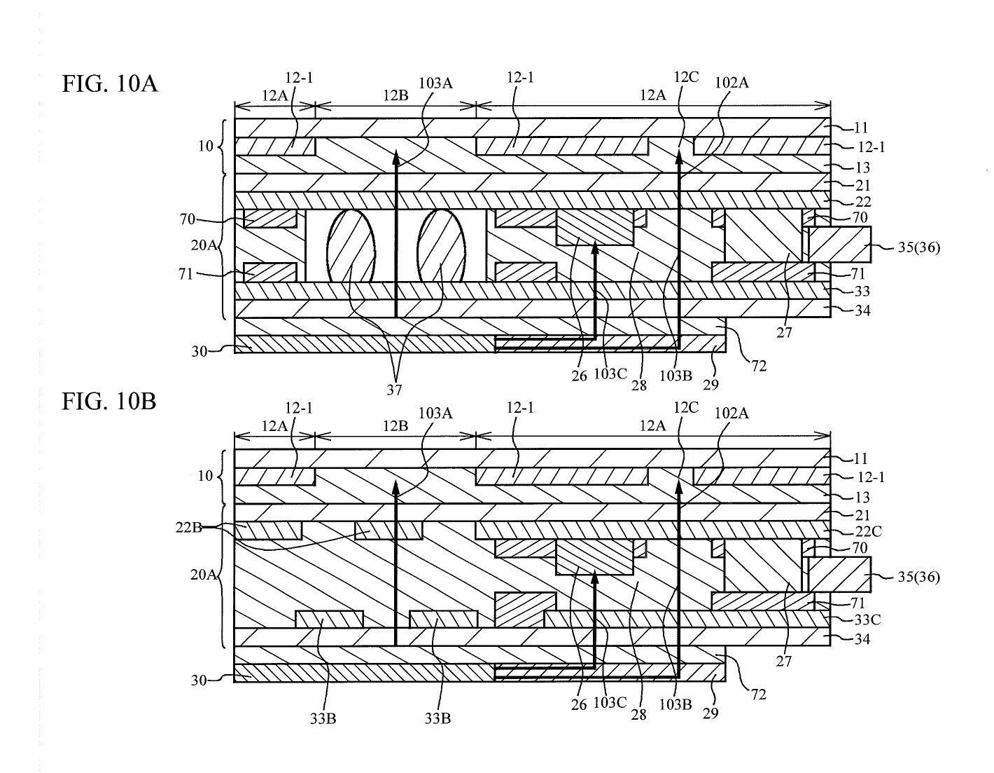

FIG. 10A is a cross-section diagram illustrating schematic configuration of a third variation of the touch panel 1 in FIG. 7A. FIG. 10B is a cross-section diagram illustrating schematic configuration of a third variation of the touch panel 2 in FIG. 7B.

As described above, in FIGS. 8A and 8B, the illuminant 30 is arranged below the lower substrate 34 (i.e., on the rear surface of the lower substrate 34). The light-guiding plate 29 is not used. The illuminant 30 is provided at a position opposite to the operation area 12B and the logo 12C.

On the other hand, in FIGS. 10A and 10B, the illuminant 30 and the light-guiding plate 29 are arranged below the lower substrate 34 (i.e., on the rear surface of the lower substrate 34). The illuminant 30 is adjacent to a side surface of the light-guiding plate 29 (i.e., the illuminant 30 is arranged on an end of the light-guiding plate 29), and is provided at a position opposite to the operation area 12B. The light-guiding plate 29 is provided at a position opposite to the logo 12C. The illuminant 30 and the light-guiding plate 29 are pasted on the rear surface of the lower substrate 34 with the adhesive 72. The adhesive 72 is an OCA (Optical Clear Adhesive) or a double-sided tape. In this case, the acceptance surface of the photoelectric converter 26 is also looking down.

Light 103A emitted from the illuminant 30 proceeds to the operation area 12B. In this case, the user can confirm light emitting of the operation area 12B. When the operation instruction is input in a dark environment, for example, the light emitting of the operation area 12B is useful. Light 103B emitted from the illuminant 30 proceeds to the logo 12C via the light-guiding plate 29. Light 103C emitted from the illuminant 30 proceeds to the photoelectric converter 26 via the light-guiding plate 29. In this case, the photoelectric converter 26 can generate the electric power by the light 103C emitted from the illuminant 30. The thermoelectric converter 27 can generate an electric power by the temperature difference between the temperature of the surface of the cover 11 and the temperature inside the touch panel 1 or 2.

In FIGS. 10A and 10B, the illuminant 30 can be miniaturized as compared with FIGS. 8A and 8B, so that a manufacturing cost can be reduced.

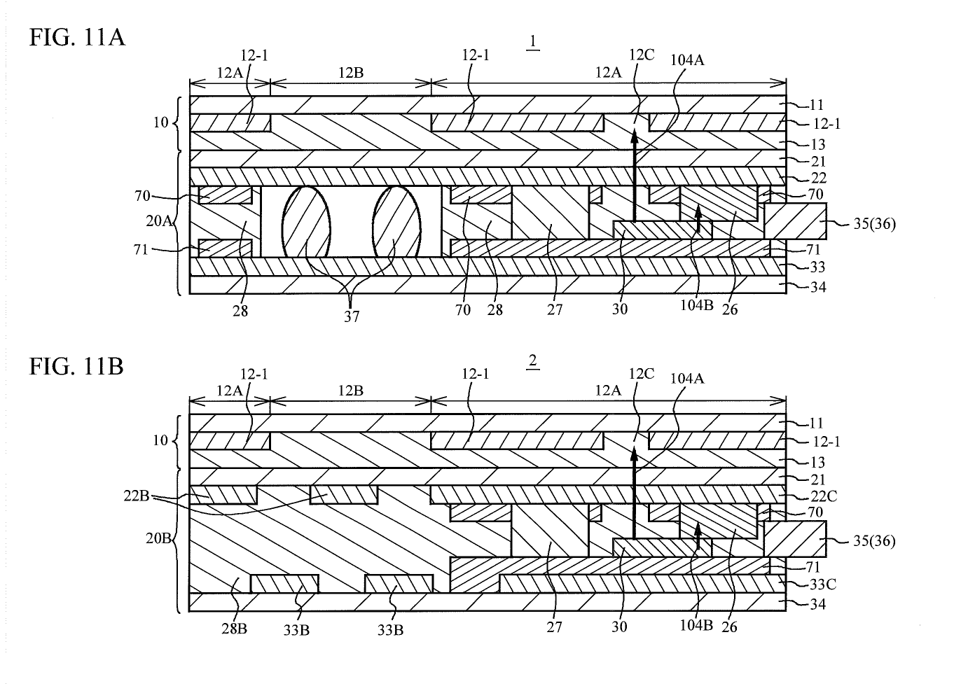

FIG. 11A is a cross-section diagram illustrating schematic configuration of a fourth variation of the touch panel 1 in FIG. 7A. FIG. 11B is a cross-section diagram illustrating schematic configuration of a fourth variation of the touch panel 2 in FIG. 7B.

As described above, in FIGS. 7A and 7B, the illuminant 30 is arranged on the light-guiding plate 29 so as to be opposite to a part of the light-guiding plate 29. On the other hand, in FIGS. 11A and 11B, the illuminant 30 is arranged above the photoelectric converter 26 so as to be opposite to a part of the photoelectric converter 26. In addition, the illuminant 30 is opposite to the logo 12C. In this case, the acceptance surface of the photoelectric converter 26 is also looking down. Light 104A emitted from the illuminant 30 proceeds to the logo 12C. Moreover, light 104B emitted from the illuminant 30 proceeds to the photoelectric converter 26.

Thus, in FIGS. 11A and 11B, the light emitted from the illuminant 30 can be directly guided to the photoelectric converter 26 and the logo 12C without using the light-guiding plate 29.

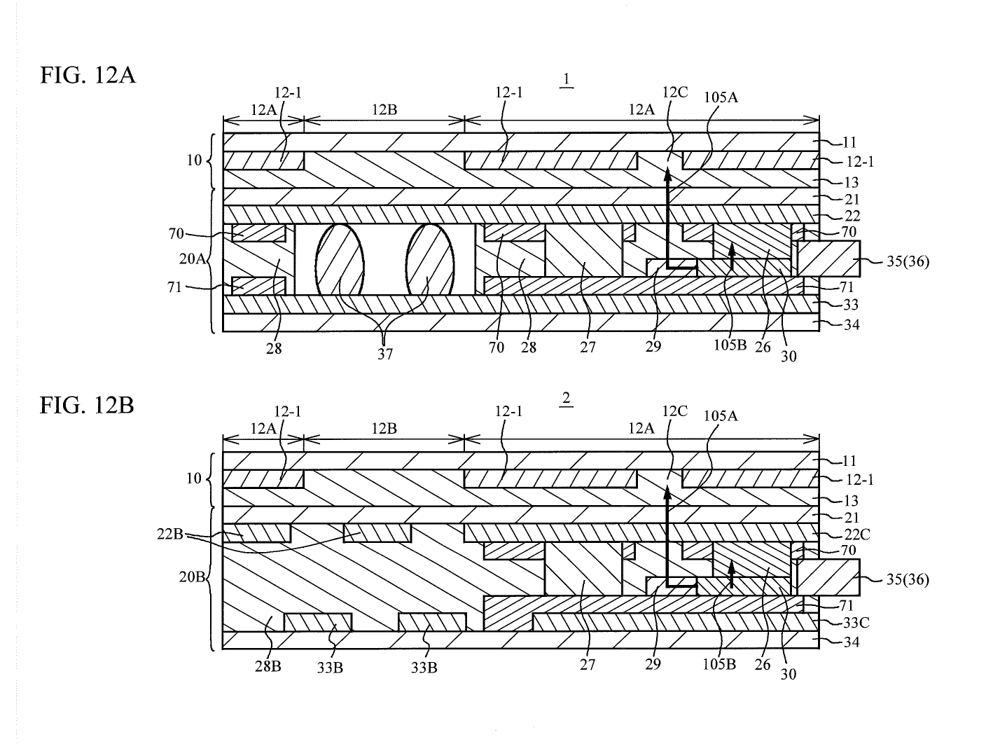

FIG. 12A is a cross-section diagram illustrating schematic configuration of a fifth variation of the touch panel 1 in FIG. 7A. FIG. 12B is a cross-section diagram illustrating schematic configuration of a fifth variation of the touch panel 2 in FIG. 7B.

As described above, in FIGS. 7A and 7B, the illuminant 30 is arranged on the light-guiding plate 29 so as to a part of the light-guiding plate 29. On the other hand, in FIGS. 12A and 12B, the illuminant 30 and the light-guiding plate 29 are arranged under the photoelectric converter 26 so as to be opposite to the photoelectric converter 26. In addition, the light-guiding plate 29 is adjacent to a side surface of the illuminant 30 and is opposite to the logo 12C. The acceptance surface of the photoelectric converter 26 is also looking down. Light 105A emitted from the illuminant 30 proceeds to the logo 12C via the light-guiding plate 29. Moreover, light 105B emitted from the illuminant 30 proceeds to the photoelectric converter 26.

Thus, in FIGS. 12A and 12B, the light emitted from the illuminant 30 can be directly guided to the photoelectric converter 26, and guided to the logo 12C via the light-guiding plate 29.

As described above, according to the present embodiment, the touch panel 1 or 2 includes: the illuminant 30 that emits the light from the logo 12C provided on the non-operation area of the cover film 10; and at least one of the photoelectric converter 26 that generates the electric power from the light emitted from the illuminant 30 and the thermoelectric converter 27 that generates the electric power by the temperature difference between the temperature of the operation surface of the touch panel and the temperature inside the touch panel. Then, the illuminant 30, and at least one of the photoelectric converter 26 and the thermoelectric converter 27 are arranged between the upper substrate 21 and the lower substrate 34, and arranged below the non-operation area of the cover film 10.

It is, therefore, possible to effectively use the light emitted from the illuminant 30 via the logo 12C which is the non-operation area of the cover film 10, or use the heat inside the apparatus (i.e., the heat inside the touch panel 1 or 2). In addition, since the illuminant 30, and at least one of the photoelectric converter 26 and the thermoelectric converter 27 are housed in the touch panel 1 or 2, the space-saving touch panel which uses effectively the light from the illuminant 30 or the heat inside the apparatus can be offered. When the illuminant 30 is also arranged below the lower substrate 34, it is possible to effectively use the light from the illuminant 30 or the heat inside the apparatus.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A touch panel comprising:
an illuminant that emits light from an opening provided on a non-operation area of a film; and
at least one of a photoelectric converter that generates an electric power based on the light emitted from the illuminant and a thermoelectric converter that generates an electric power based on a temperature difference between a temperature of an operation surface of the touch panel and a temperature inside the touch panel;
wherein the illuminant and the at least one of the photoelectric converter and the thermoelectric converter are arranged between an upper substrate and a lower substrate of the touch panel, and arranged below the non-operation area of the film.

2. The touch panel as claimed in claim 1, further comprising a light-guiding plate adjacent to the illuminant and an acceptance surface of the photoelectric converter.

3. The touch panel as claimed in claim 2, wherein the illuminant is adjacent to any one of an upper surface and a side surface of the light-guiding plate.

4. The touch panel as claimed in claim 1, wherein the illuminant is adjacent to the acceptance surface of the photoelectric converter and is opposite to the opening.

5. The touch panel as claimed in claim 1, wherein the illuminant is adjacent to an acceptance surface of the photoelectric converter and a side surface of a light-guiding plate, and the light-guiding plate is opposite to the opening.

6. The touch panel as claimed in claim 1, wherein an acceptance surface of the photoelectric converter is looking down.

7. A touch panel comprising:
an illuminant that emits light from an opening provided on a non-operation area of a film; and
at least one of a photoelectric converter that generates an electric power based on the light emitted from the illuminant and a thermoelectric converter that generates an electric power based on a temperature difference between a temperature of an operation surface of the touch panel and a temperature inside the touch panel;
wherein the at least one of the photoelectric converter and the thermoelectric converter is arranged between an upper substrate and a lower substrate of the touch panel, and arranged below the non-operation area of the film, and
wherein the illuminant is arranged below the lower substrate of the touch panel.

8. The touch panel as claimed in claim 7, further comprising a light-guiding plate that is arranged below the lower substrate of the touch panel, adjacent to the illuminant, and opposite to the opening and an acceptance surface of the photoelectric converter.

9. The touch panel as claimed in claim 1, wherein the thermoelectric converter includes a through-hole for arranging at least one of the photoelectric converter and the illuminant.

10. The touch panel as claimed in claim 1, wherein the photoelectric converter includes a penetration hole that penetrates a part of the light emitted from the illuminant to the opening.

11. The touch panel as claimed in claim 1, wherein the illuminant is any one of a LED (Light Emitting Diode), an organic EL (Electro-Luminescence), and a liquid crystal panel.

12. The touch panel as claimed in claim 1, wherein the touch panel is a resistive membrane touch panel or a projected capacitive touch panel.

13. The touch panel as claimed in claim 7, wherein the thermoelectric converter includes a through-hole for arranging at least one of the photoelectric converter and the illuminant.

14. The touch panel as claimed in claim 7, wherein the photoelectric converter includes a penetration hole that penetrates a part of the light emitted from the illuminant to the opening.

15. The touch panel as claimed in claim 7, wherein the illuminant is any one of a LED (Light Emitting Diode), an organic EL (Electro-Luminescence), and a liquid crystal panel.

16. The touch panel as claimed in claim 7, wherein the touch panel is a resistive membrane touch panel or a projected capacitive touch panel.
